(19) United States
(12) Patent Application Publication
(10) Pub. No.: US 2006/0170004 A1
(43) Pub. Date: Aug. 3, 2006

(54) Semiconductor device and manufacturing method of the same

(76) Inventors: Hisashi Toyoda, Shibukawa (JP); Kouichi Arai, Fujioka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/339,566

(22) Filed: Jan. 26, 2006

(30) Foreign Application Priority Data
Jan. 31, 2005 (JP) 2005-023246

(51) Int. Cl. H01L 31/109

(52) U.S. Cl. 257/197

(57) ABSTRACT

A bipolar transistor for communication apparatus having improved power gain and high frequency output characteristics is described. The bipolar transistor includes an outer base layer connecting an intrinsic base region with a base electrode, with a planar shape thereof being in a U form. The long sides of the collector electrode and an emitter electrode are disposed parallel to each other within a plane parallel to a main surface of a substrate, and plural collector electrodes and plural emitter electrodes are alternately arranged. On the other hand, the base electrode is set outside a line connecting the collector electrode and the emitter electrode at one end thereof, and the long side of the base electrode is so disposed as to intersect at right angles with the respectively long sides of the collector electrode and the emitter electrode.

### CROSS-REFERENCE TO RELATED APPLICATION

The present application claims priority from Japanese Patent Application No. 2005-023246 filed on January 31, 2005, the content of which is hereby incorporated by reference into this application.

### BACKGROUND OF THE INVENTION

This invention relates to a semiconductor device and a manufacturing technique therefor. More particularly, the invention relates to a technique effective for application to sophistication of RF bipolar transistors.

For semiconductor devices directed to the use for communication apparatus such as digital cordless telephones, wireless LAN and the like, bipolar transistors ensuring higher speed operation than MOS transistors have been in use. For the sophistication of this type of RF (radio frequency) bipolar transistors for communication apparatus, it is important to improve power gain (PG) and RF output characteristics.

Japanese Unexamined Patent Publication No. Hei 7 (1995) 094521 discloses a high-speed technique of bipolar transistors for communication apparatus. The bipolar transistor set out in this patent publication includes an emitter layer formed over a surface of a semiconductor device, an emitter extraction electrode that is formed on the semiconductor substrate so as to surround the emitter layer therewith, is in contact with the emitter layer and has a recess over the emitter layer, a base layer part of which is formed, at least, over the emitter layer within the recess region of the emitter extraction electrode, and a collector layer formed over the base layer within the recess region. The collector layer is self-alignedly formed, for example, by burying, after formation of the base layer, a conductor layer within a region surrounded with the emitter extraction electrode. According to this transistor structure, the collector layer is formed not only in the semiconductor substrate, but also on the base layer formed over the semiconductor substrate, so that no burying layer serving as a current path of a collector current within the semiconductor substrate is necessary. Thus, the transistor can be correspondingly microfabricated, thereby ensuring high-speed operations Japanese Unexamined Patent Publication No. Hei 9 (1997) 199513 discloses a technique wherein reductions in collector resistance of a bipolar transistor and also of manufacturing costs are realized. An instance of a bipolar transistor set forth in this patent publication includes, on a semiconductor substrate of a first conduction type, a collector region of a second conduction type, a base region of the first conduction type, an emitter region of the second conduction type, an insulating layer, a collector electrode, an emitter electrode, and a base electrode. The base region is formed on the surface of a collector region, and the emitter region is formed on the surface of the base region. The insulating layer formed over the main surface of the semiconductor substrate has openings arriving at part of each of the collector region, emitter region and base region, and the collector electrode, emitter electrode and base electrode are, respectively, formed within these openings. When a length of the opening in a lengthwise direction where the emitter electrode is formed is taken as L and a width of a second opening along a direction intersecting at right angles with the lengthwise direction is taken as S, the collector resistance is reduced by setting a value of L/S at 100 or over,

### SUMMARY OF THE INVENTION

FIG. 17 is a plan view of an essential part of a bipolar transistor of a type which the inventors checked, and FIG. 18 is a sectional view taken along line A-A of FIG. 17.

This bipolar transistor is formed in an epitaxial layer 101 of a semiconductor substrate 100 (hereinafter referred to simply as substrate) made of single crystal silicon. The substrate 100 is formed with an n⁺-type buried layer 102 constituting part of a collector region, and the upper epitaxial layer 101 is formed with an n-type collector region 103.

An n-type collector extraction region 104 arriving at the n⁺-type buried layer 102 at the bottom thereof is formed at part of the collector layer 103, and a p-type intrinsic base region 105 is formed at other part. The collector extraction region 104 and the intrinsic base region 105 are mutually isolated from each other by means of a filed insulating film 107 formed on the surface of the epitaxial layer 101.

An outer base layer 108 made of a p-type polysilicon film is formed above the intrinsic base region 105, and an emitter extraction layer 109 made of an n-type polysilicon film is formed above the emitter region 106. The outer base layer 108 has a rectangular, planar form sufficient to widely cover the intrinsic base region 105 at the upper portion thereof other than the upper portion of the emitter region 106 and also the upper portion of the field insulating film 107 formed around the intrinsic base region 105. The intrinsic base region 105 is formed by permitting a p-type impurity (boron) in the polysilicon film serving as the outer base layer 108 to be diffused in part of the surface of the collector region 103. The emitter region 106 is also formed by permitting an n-type impurity (phosphorus) in the polysilicon film of the emitter extraction layer 109 to be diffused in part of the surface of the intrinsic base region 105.

Ann interlayer insulating film 110 is formed as an upper layer of the emitter extraction layer 109. Above the interlayer insulating film 110, there are, respectively, formed a collector electrode 111C, emitter electrode 111E and base electrode 111B.

The collector electrode 111C is located above the collector extraction electrode 104 and is electrically connected to the collector extraction region 104 through a metal plug 115 formed inside a contact hole 112 of the interlayer insulating film 110. The emitter electrode 111E is disposed above the emitter extraction layer 109 and is electrically connected to the emitter extraction layer 109 through the metal plug 115 formed inside a contact hole 114 of the interlayer insulating film 110. The base electrode 111B is disposed above the field insulting film 107 and is electrically connected to the outer base layer 108 through the metal plug 115 formed inside a contact hole 113 of the interlayer insulating film 110.

The collector electrode 111C, emitter electrode 111E and base electrode 111B, respectively, have a rectangular planar form. The emitter electrode 111E and the base electrode 111B are, respectively, provided plurally in number and the plural electrodes 111E and 111B are alternately arranged above the outer base layer 108, and the collector electrode 111C is arranged adjacent to the base electrode 111B in a region where no outer base layer 108 is formed.

Such a bipolar transistor arranged as set out hereinabove has the outer base layer 108 connecting the intrinsic base region 105 and the base electrode 111B therewith in such a way that the outer base layer 108 widely covers the upper portion of the intrinsic base region 105 except for the upper portion of the emitter region 106 and the upper portion of the field insulating film 107 provided therearound. This leads to an increasing base-collector MOS capacitance (C_{BX}) occurring below the outer base layer 108. Thus, an output capacitance (Cᵣₑ) defined by the sum (C_{BX}+C_{jc}) of the base-collector MOS capacitance (C_{BX}) and the collector-base junction capacitance (C_{jc}) increases, so that there arises a problem of lowering a power gain (PG) as shown by the equation (1).

$$POWER GAIN ( PG ) = 10 log [ \frac{{f}_{T}}{8 \cdot π \cdot {f}^{2} \cdot rb \cdot {C}_{re}} ] \qquad ( 1 )$$

wherein f_{T} is a cutoff frequency, f is a frequency, rb is a base resistance, and Cᵣₑ is an output capacitance.

Accordingly, in order to improve the power gain (PG) of the bipolar transistor, it is important how to develop an element structure which is capable of reducing the base-collector MOS capacitance (C_{BX})

The bipolar transistor arranged as set out hereinabove has the base electrode 111B arranged between the emitter electrode 111E and the collector electrode 111C. This eventually permits the emitter electrode 111E and the collector electrode 111C to be set far from each other, resulting in a large collector resistance (Rc). This brings about a problem of lowering a cutoff frequency (F_{T}) as will be seen from the following equation (2). The increase of the collector resistance (Rc) also causes a problem of lowering 1 dB gain compression output power.

$$\frac{1}{2 π {f}_{T}} = τ e + \frac{{W}_{B}^{2}}{η {D}_{n}} + \frac{{X}_{c}}{{2}_{vsat}} + \frac{{C}_{BE} + {C}_{BC}}{{g}_{m}} + {R}_{C} \cdot {C}_{BC} \qquad ( 2 )$$

wherein f_{T} is a cutoff frequency, Vₛₐₜ is a saturation rate of carrier, gₘ is a mutual conductance, πₑ is an emitter transit time, X_{C} is a width of a depletion layer of collector, R_{C} is a collector resistance, W_{B} is a base width, C_{BE} is an emitter-base capacitance, Dₙ is a diffusion constant of electron, and C_{BS} is a base-collector capacitance.

An object of the invention is to provide a technique capable of improving a power gain of a bipolar transistor.

Another object of the invention is to provide a technique capable of improving high frequency output characteristics of a bipolar transistor.

The above and other objects and novel features of the invention will become apparent from the following description of the specification and the accompanying drawings.

A typical embodiment of the invention is briefly summarized below.

A semiconductor device according to the invention includes a bipolar transistor, which includes a collector region, an intrinsic base region and an emitter region formed over a main surface of a semiconductor substrate, respectively, a collector electrode electrically connected to the collector region, a base electrode electrically connected to the intrinsic base region via an outer base layer, and an emitter electrode electrically connected to the emitter region via an emitter extraction layer, wherein the collector electrode and the emitter electrode are, respectively, provided plurally in number and the plural collector electrodes and plural emitter electrodes are alternately disposed side by side, and the outer base layer has a planar shape of a U form.

The effects and advantages of the typical embodiment are briefly described below.

Because an area of the outer base layer connected with the intrinsic base region and the base electrode can be made small, the base-collector MOS capacitance (C_{BX}) occurring below the outer base layer can be lessened, thereby leading to an improvement of power gain (PG).

Because the collector electrode and the emitter electrode can be set close to each other, the collector resistance (Rc) can be made small, thereby ensuring improved cutoff frequency (f_{T}) and 1 dB gain compression output power.

### BRIEF DESCRIPTION OF THE DRAWINGS

FIG. 1 is a plan view showing an essential part of a bipolar transistor according to one embodiment of the invention;

FIG. 2 is also a plan view showing an essential part of the bipolar transistor according to the one embodiment of the invention;

FIG. 3 is a sectional view of a semiconductor substrate, taken along line A-A of FIG. 1;

FIG. 4 is a sectional view of the semiconductor substrate, taken along line B-B of FIG. 1;

FIG. 5 is a graph showing the results of power gain of the bipolar transistor according to the embodiment of the invention and also of another type of bipolar transistor checked by the inventors;

FIGS. 6(a) and 6(b) are, respectively, a block diagram in which FIG. 6(a) is a block diagram showing a high frequency front end unit of a 2 GHz digital codeless telephone to which the bipolar transistor according to the one embodiment of the invention is applied and FIG. 6(b) is a block diagram showing a high frequency front end unit of a 5 GHz digital codeless telephone to which the bipolar transistor according to the one embodiment of the invention is applied;

FIG. 7 is a sectional view of a semiconductor substrate showing a step of manufacturing a bipolar transistor according to the one embodiment of the invention;

FIG. 8 is a sectional view of the semiconductor substrate showing another step of manufacturing the bipolar transistor subsequent to FIG. 7;

FIG. 9 is a plan view of the semiconductor substrate showing a further step of manufacturing the bipolar transistor subsequent to FIG. 7;

FIG. 10 is a sectional view of the semiconductor substrate showing a still further step of manufacturing the bipolar transistor subsequent to FIG. 7;

FIG. 11 is a sectional view of the semiconductor substrate showing another step of manufacturing the bipolar transistor subsequent to FIGS. 9 and 10;

FIG. 12 is a plan view of the semiconductor substrate showing another step of manufacturing the bipolar transistor subsequent to FIG. 11;

FIG. 13 is a plan view of the semiconductor substrate showing a further step of manufacturing the bipolar transistor subsequent to FIG. 12;

FIG. 14 is a sectional view of the semiconductor substrate showing a further step of manufacturing the bipolar transistor subsequent to FIG. 12;

FIG. 15 is a sectional view of the semiconductor substrate showing a still further step of manufacturing the bipolar transistor subsequent to FIG. 12;

FIG. 16 is a plan view showing an essential part of a bipolar transistor according to another embodiment of the invention;

FIG. 17 is a plan view. showing an essential part of a bipolar transistor checked by the inventors;

FIG. 18 is a sectional view of a semiconductor substrate, taken along line A-A of FIG. 17; and

FIG. 19 is a sectional view showing an essential part of a bipolar transistor according to a further embodiment of the invention.

### DETAILED DESCRIPTION OF THE PREFERRED EMBODIMENTS

The embodiments of the invention are described in detail with reference to the accompanying drawings. It is to be noted that like reference numerals indicate like members or parts throughout the drawings unless otherwise indicated.

### EMBODIMENT 1

This embodiment is directed to an application to a bipolar transistor for power amplifier which is built in communication apparatus such as digital codeless telephones whose frequency is 1 GHz or over, wireless LAN and the like.

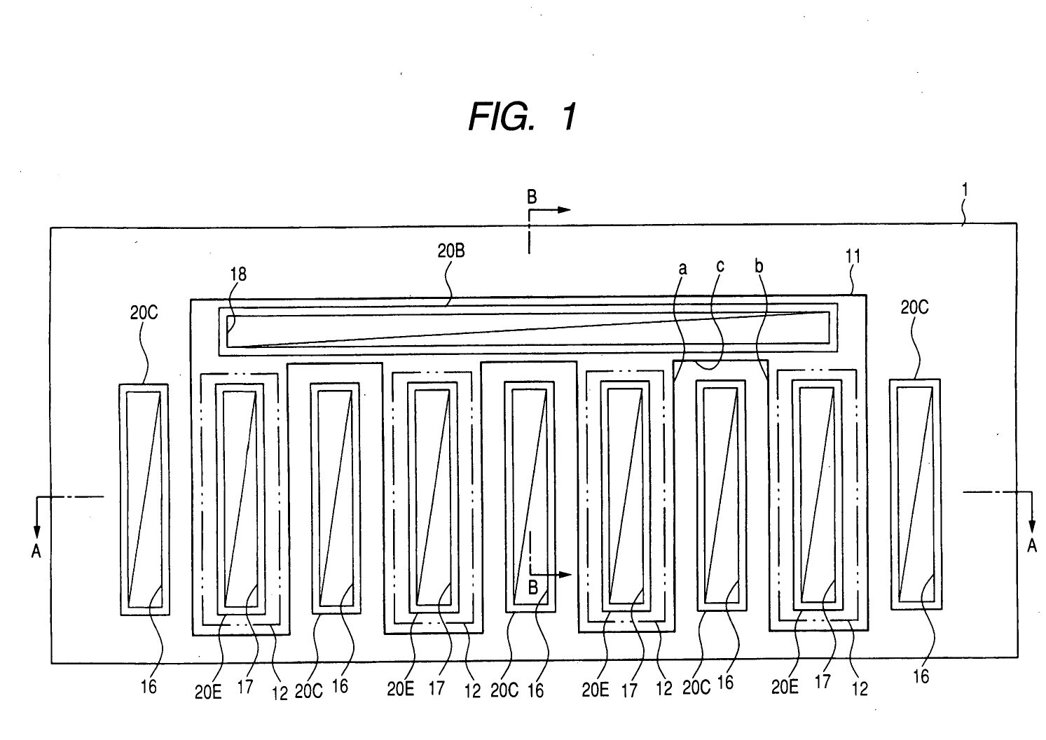

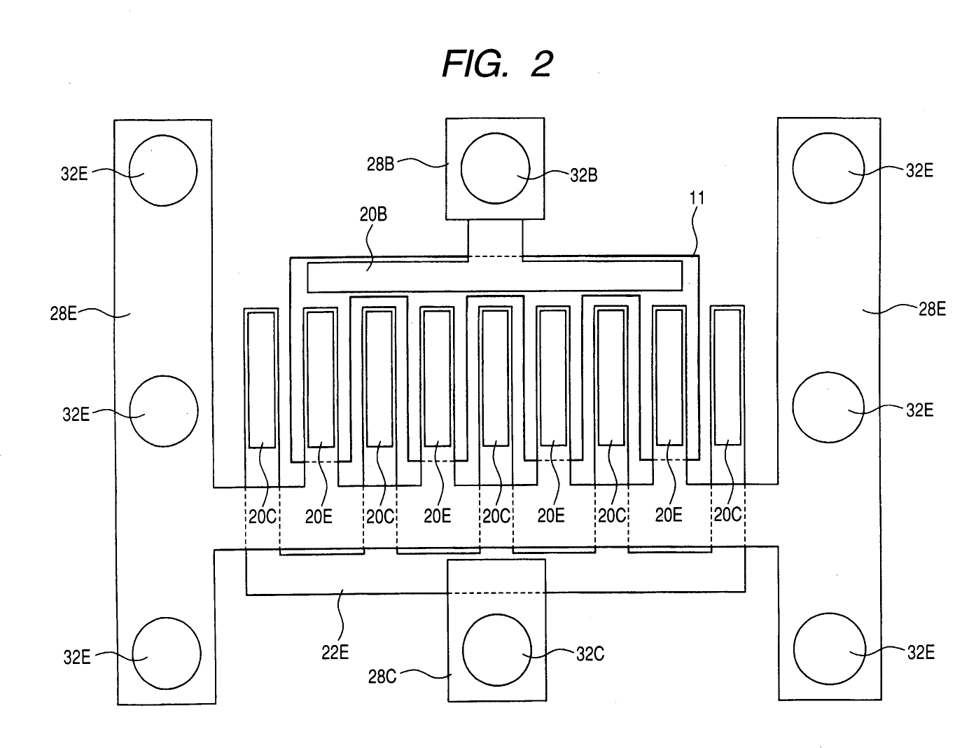

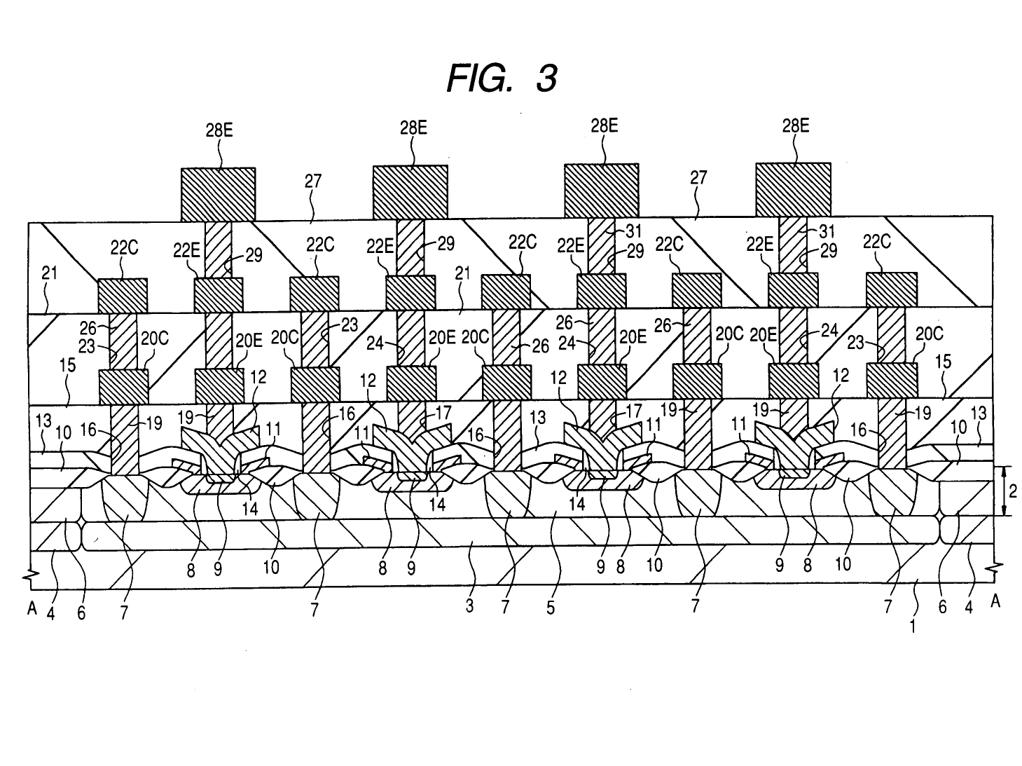

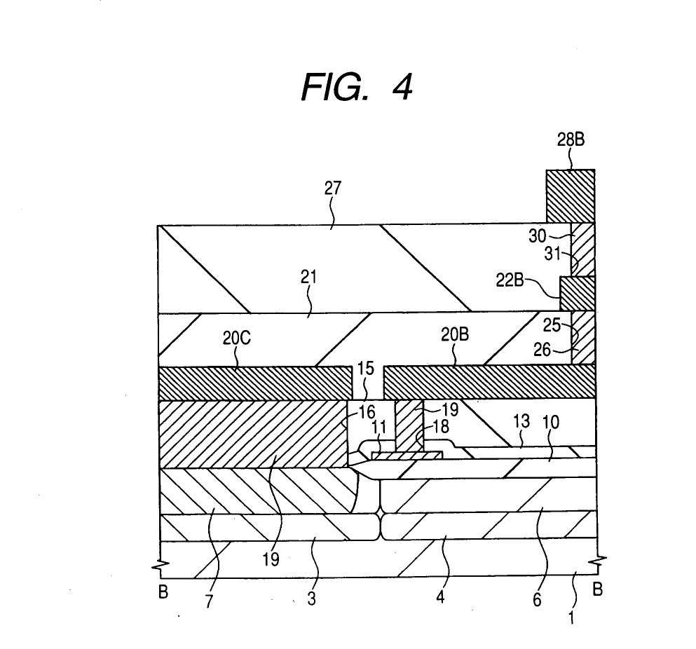

FIGS. 1 and 2 are, respectively, a plan view of an essential part of a bipolar transistor according to this embodiment. FIG. 3 is a sectional view taken along line A-A of FIG. 1 and FIG. 4 is a sectional view taken along line B-B of FIG. 1. It will be noted that for facilitating a planar layout of individual elements and wirings of a bipolar transistor to be easily seen, only part of individual members is shown in FIGS. 1 and 2.

The bipolar transistor according to this embodiment is formed, for example, at an epitaxial layer 2 made of a Si—Ge semiconductor, which is formed on the main surface of a substrate 1 made of p-type single crystal silicon. A semiconductor region indicated at 3 and formed on the substrate 1 is an n⁺-type buried layer that constitutes part of a collector region, and a semiconductor region indicated at 4 is a p⁺-buried layer for isolation. A semiconductor region indicated at 5 formed in the epitaxial layer 2 is an n-type collector region, and a semiconductor region indicated at 6 is a p-type field region. The bipolar transistor formed on the Si—Ge semiconductor formed by combination of silicon and germanium is small in consumption power and/or noise and works at high speed, thus being suited to receive, transmit and process data of large capacity at high speed.

At part of the collector region 5 formed at the epitaxial layer 2, there is formed an n-type collector extraction region 7 whose bottom arrives at the n⁺-type buried layer 3, and at other part thereof, a p-type intrinsic base region 8 is formed. Moreover, at part of the surface of the intrinsic base region 8, there is formed an n-type emitter region 9. The collector extraction region 7 and the intrinsic base region 8 are isolated from each other by means of a field insulating film 10 made of a silicon oxide film and formed on the surface of the epitaxial layer 2.

An outer base layer 11, part of which extends over the field insulating film 10, is formed above the intrinsic base region 8. The outer base layer 11 is made of a p-type polysilicon film. As will be described hereinafter, the intrinsic region 8 is formed by diffusing a p-type impurity (boron), existing in the polysilicon film forming the outer base layer 11, into part of a surface of the collector region 5. The outer base layer 11 of this embodiment has a planar shape of a U form. The outer base layer 11 is constituted of a first portion (a) and a second portion (b) that are positioned at opposite sides of a collector electrode 20C, and a third portion (c) that is positioned along a direction intersecting (substantially at right angles) with the first portion (a) and the second portion (b) and is connected to the first and second portions, respectively. More particularly, the planar shape of the outer base layer 11 parallel to the main surface of the semiconductor substrate is in a U form made of the first, second and third portions. The planar shape of the outer base layer 11 shown in FIGS. 1 and 2 is depicted as being bipectinate wherein two U forms are laterally laid and parts thereof are connected with each other. The outer base layer 11 may be constituted by a single U form or by three or more U forms being connected with each other.

An n-type emitter extraction layer 12 adjacent to the emitter region 9 is formed above the emitter region 9. The emitter extraction layer 12 is made of an n-type polysilicon film, and is isolated from the outer base layer 11 by means of a silicon oxide film 13 and a side wall insulating film 14. As will be described hereinafter, the emitter region 9 is formed by diffusing an n-type impurity (phosphorus), existing in the polysilicon film constituting the emitter extraction layer 12, above the emitter region 9, into part of the surface of the intrinsic base region 8.

Although not shown in the figures, the collector extraction region 7 and the intrinsic base region 8, respectively, have a rectangular, planar shape. The emitter region 9 and the upper emitter extraction layer 12, respectively, have a rectangular, planar shape. The collector extraction region 7 and intrinsic base region 8 are, respectively, provided plurally in number and are alternately set side by side, and are isolated from each other by means of the filed insulating film 10. A plurality of the collector extraction regions 7 are located one by one inside the outer base layer 11 having a planar shape of a U form except for the collection extraction region 7 at opposite ends.

An interlayer insulating film 15 made of a silicon oxide film is formed over the emitter extraction layer 12, and a first metal wiring layer constituting a collector electrode 20C, an emitter electrode 20E and a base electrode 20B is formed over the interlayer insulating film 15.

The collector electrode 20C is disposed above the collector extraction region 7 and is electrically connected to the collector extraction region 7 via a metal plug 19 formed within a contact hole 16 of the interlayer insulating film 15. The collector electrode 20C has a rectangular, planar form, like the collector extraction region 7.

The emitter electrode 20E is located above the emitter extraction layer 12 and is electrically connected to the emitter extraction layer 12 via a metal plug 19 formed within a contact hole 17 of the interlayer insulating film 15. The emitter electrode 20E has a rectangular, planar form, like the emitter region 9 and the emitter extraction layer 12.

As stated hereinabove, the collector extraction regions 7 and the intrinsic base regions 8 that are, respectively, plural in number are alternately arranged side by side, and the emitter region 9 is formed at part of the surface of the intrinsic base region 8. Accordingly, a plurality of the collector regions 20C disposed above the collector extraction regions and a plurality of the emitter electrodes 20E disposed above the emitter regions 9 are alternately, collaterally arranged over the interlayer insulating film 15.

The plurality of collector electrodes 20C and the plurality of the emitter electrodes 20E are arranged parallel to each other with respect to the long sides thereof within a plane parallel to the main surface of the substrate 1. The collector electrode 20C and the emitter electrode 20E stand in the same line with respect to the central portions thereof. As set out hereinabove, a plurality of collector extraction regions 7 are, respectively, put in position one by one at an inner side of the outer base layer 11 having the planar shape of a U form, and thus, a plurality of collector electrodes 20C are also set out one by one at the inner side of the outer base layer 11 except for the collector electrode 20C at the opposite ends, respectively.

The base electrode 20B is put in position above the outer base layer 11 and is electrically connected to the outer base layer 11 via a metal plug 19 formed within a contact hole 18 of the interlayer insulating film 15. The base electrode 20B has a rectangular, planar shape, like the collector electrode 20C and the emitter electrode 20E, with a central portion thereof not standing in line connecting the central portion of the collector electrode 20C and the central portion of the emitter electrode 20E. More particularly, the base electrode 20B of this embodiment has each long side thereof which is so arranged as to intersect at right angles with individual long sides of the collector electrode 20C and the emitter electrode 20E and is located at the outside relative to a line connecting the collector electrode 20C and the emitter electrode 20E each at one end thereof.

An interlayer insulating film 21 made of a silicon oxide film is formed above the first metal wiring layer, and second metal wiring layers 22C, 22E and 22B are, respectively, formed above the interlayer insulating film 21. The second metal wiring layer 22C is electrically connected to the collector electrode 20C via a metal plug 26 formed within a contact hole 23 of the interlayer insulating film 21. The second metal wiring layer 22E is electrically connected to the emitter electrode 20E via a metal plug 26 formed within a contact hole 24 of the interlayer insulating film 21. The second metal wiring layer 22B is electrically connected to the base electrode 20B via a metal plug 26 formed within a contact hole 25 of the interlayer insulating film 21.

An interlayer insulating film 27 formed of a silicon oxide film is formed over the second metal wiring layers 22C, 22E and 22B. Third metal wiring layers 28C, 28E and 28B are, in turn, formed on the interlayer insulating film 27. The third metal wiring layer 28E is electrically connected to the second metal wiring layer 22E via a meta plug 31 formed within a contact hole 29 of the interlayer insulating film 27. The third metal wiring layer 28B is electrically connected to the second metal wiring layer 22B via metal plug 31 formed within a contact hole 30 of the interlayer insulating film 27. Although not shown, the third metal wiring layer 28C is electrically connected to the second metal wiring layer 22C via a metal plug formed within a contact hole of the interlayer insulating film 27.

As shown in FIG. 2, part of the third metal wiring layer 28C serves as a bonding pad 32C, part of the third metal wiring layer 28E serves as a bonding pad 32E, and part of the third metal wiring layer 28B serves as a bonding pad 32B.

In this way, the bipolar transistor of the embodiment is arranged such that the outer base layer 11, which connects the intrinsic base region 8 and the base electrode 20B therewith, has a planar shape that is in a U form. The long side of each collector electrode 20C and the long side of each emitter electrode 20E are arranged parallel to each other within the plain parallel to the main surface of the substrate 1, and the collector electrodes 20C and the emitter electrodes 20E are alternately arranged side by side. On the other hand, the base electrode 20B is set at the outside of a line connecting one end of each individual collector electrode 20C and one end of each individual emitter electrode 20E. The long side of the base electrode 20B is so arranged as to be intersected at right angles with the long sides of each individual collector electrode 20C and each individual emitter electrode 20E.

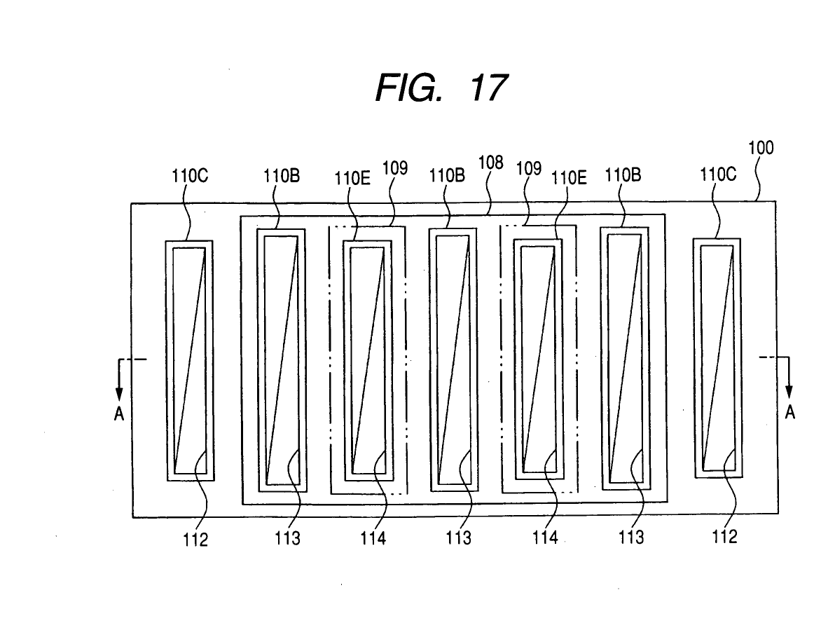

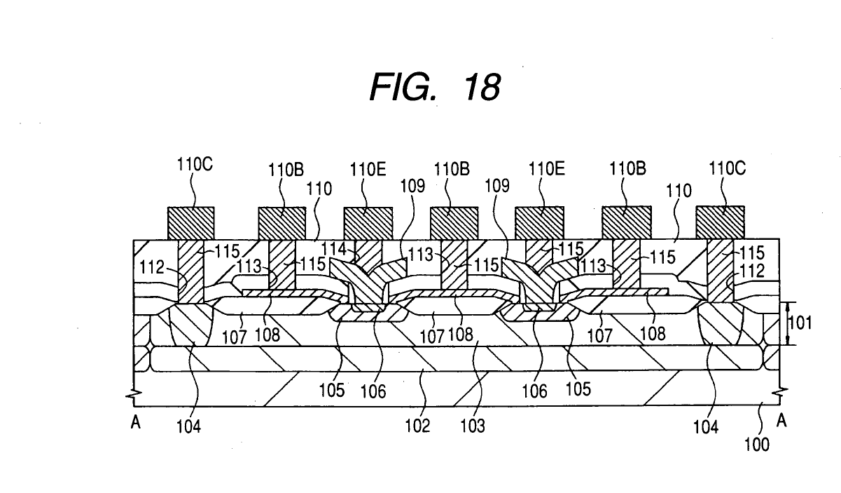

According to the arrangement as set out hereinabove, the bipolar transistor of this embodiment can be made smaller in area of the outer base layer 11 than the bipolar transistor shown in FIGS. 17 and 18, with a smaller base-collector MOS capacitance (C_{BX}) produced below the outer base layer 108, thus ensuring an improved power gain (PG).

When compared with the bipolar transistor shown in FIGS. 17 and 18, the distance between the collector electrode 20C and the emitter electrode 20E becomes smaller, so that the resulting collector resistance (R_{C}) can be made smaller, thus enabling one to improve the cutoff frequency (f_{T}) and 1 dB gain compression output power.

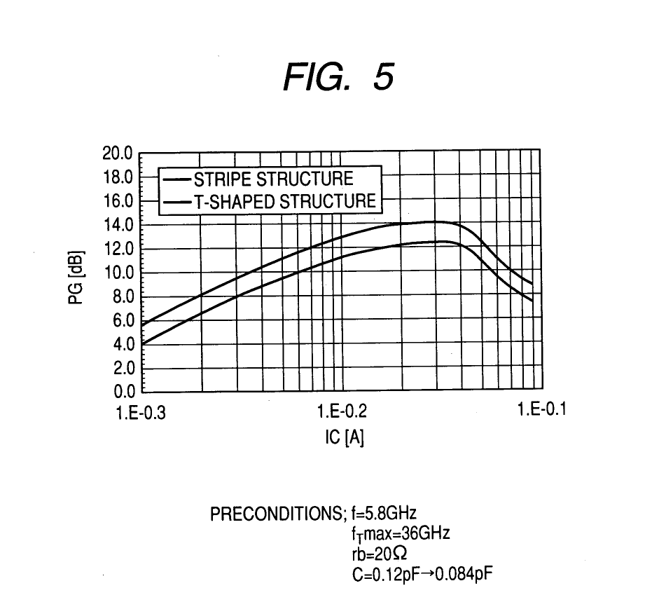

FIG. 5 is a graph showing the results of power gain (PG) of the bipolar transistor of this embodiments and the bipolar transistor shown in FIGS. 17 and 18. According to our preliminary calculation, the power gain (PG) could be improved by about 2.0 dB by the reducing effect of the base-collector MOS capacitance (C_{BX}).

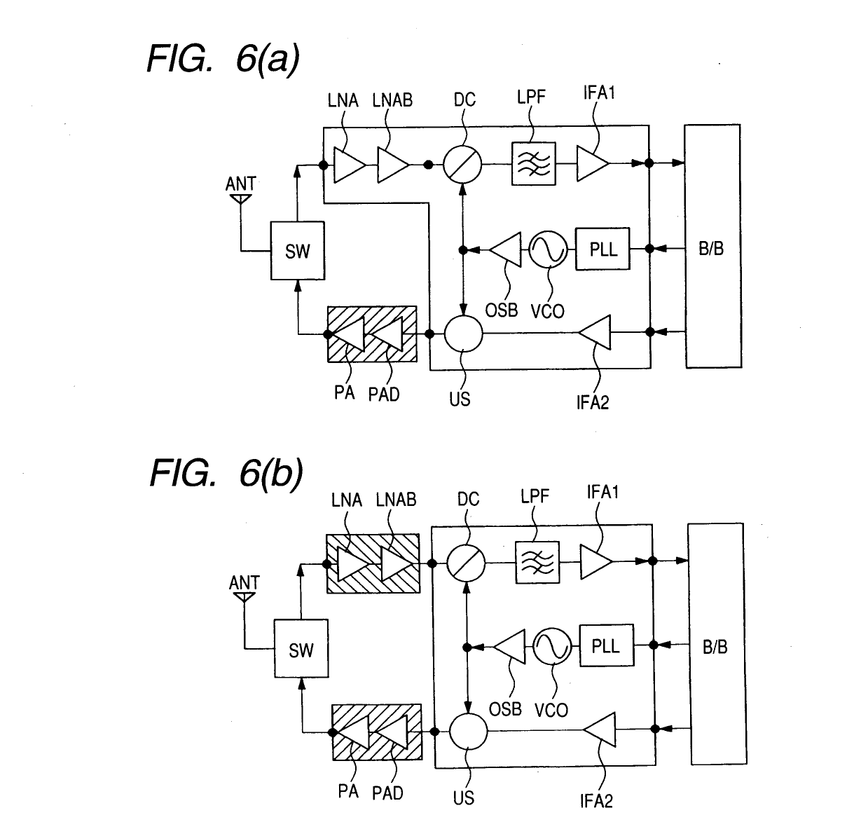

FIGS. 6(a) and 6(b) show an instance of an application of the bipolar transistor of the embodiment to a front end unit of a digital codeless telephone for high frequency signal in which FIG. 6(a) is a circuit block diagram showing a front end unit of a 2.4 GHz band digital codeless telephone and FIG. 6(b) is a circuit block diagram showing a front end unit of a 5.8 GHz band digital codeless telephone.

The front end unit of the digital codeless telephone is provided with an antenna ANT, a transmitting and receiving signal changeover switch SW and a base band processing unit B/B. Moreover, there are provided, between the transmitting and receiving signal changeover switch SW and the base band processing unit B/B, a reception group of a low noise amplifier LNA, a low noise amplifier buffer circuit LNAB, a down converter circuit DC, a low pass filter LPF, and an IF (intermediate frequency) amplifier IFAI and a transmission group of a power amplifier PA, a power amplifier drive circuit PAD, an up converter circuit UC and an IF amplifier IFA2, and a group of a PLL (phase locked loop ) frequency synthesizer, a voltage controlled oscillator (VOC) for radio frequency and an output buffer circuit OSB for oscillation circuit. The bipolar transistor of this Embodiment 1 is applied to the power amplifier PA of the reception amplifier and the drive circuit PAD in case of the 2.4 GHz band digital codeless telephone. Alternatively, with the 5.8 GHz band digital codeless telephone, the bipolar transistor is applied to the power amplifier PA for transmission amplifier and the drive circuit PAD, and also to the low noise amplifier LNA for the reception group and the low noise amplifier buffer circuit LNAB.

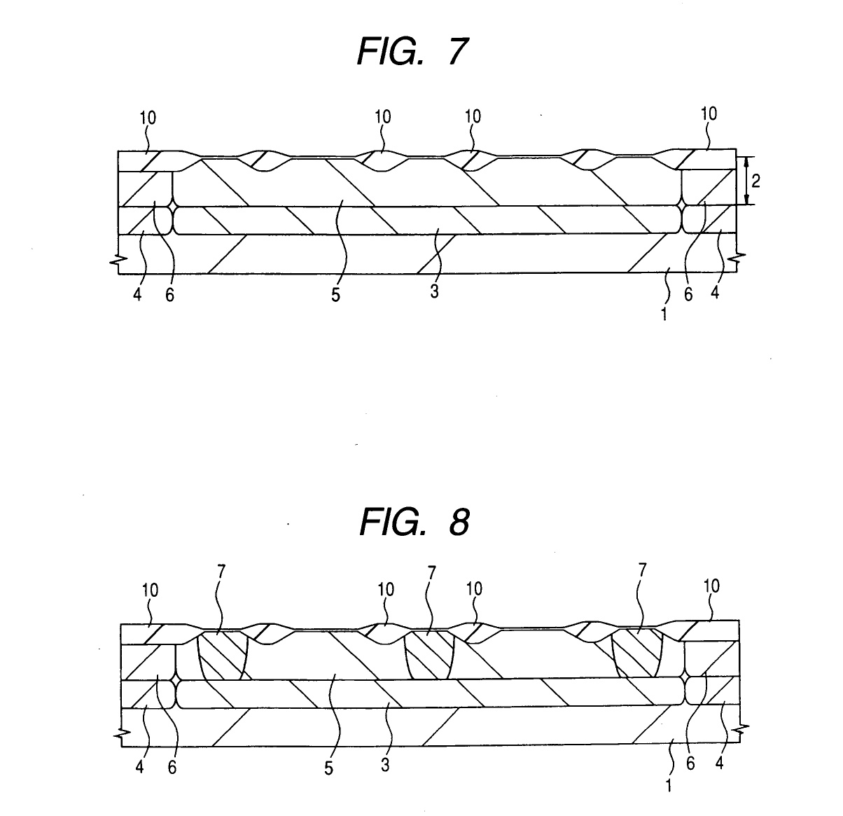

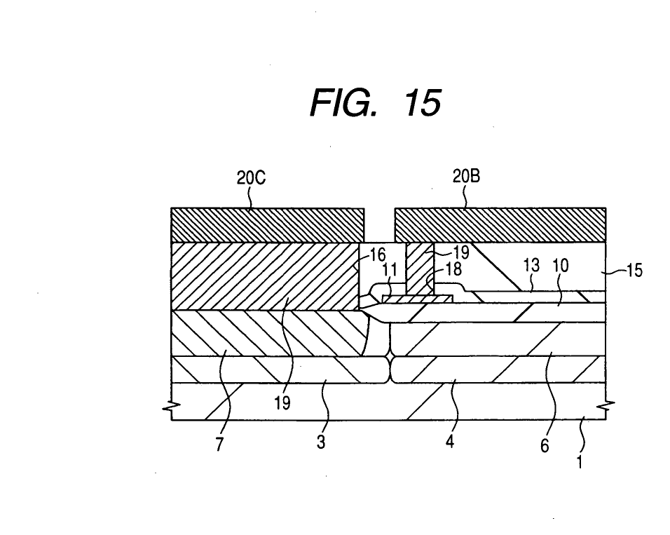

Next, an instance of a manufacturing method of the bipolar transistor of the embodiment is described in the order of steps with reference to FIGS. 7 to 15.

Initially, as shown in FIG. 7, an n-type impurity (arsenic) is ion implanted into part of the main surface of a substrate 1 made of p-type single crystal silicon, and a p-type impurity (boron) is ion implanted into other part to form an n⁺-type buried layer 3 and a p⁺-type buried layer 4 for isolation. Thereafter, an epitaxial layer 2 made of n-type Si is grown over the substrate 1. Next, an n-type impurity is ion implanted into part of the epitaxial layer 2, and a p-type impurity is ion implanted into other part to form an n-type collector region 5 and a p-type field region 6. Subsequently, the epitaxial layer 2 is oxidized in the surface thereof according to a known LOCOS method, thereby forming a field insulating film 10 for element isolation.

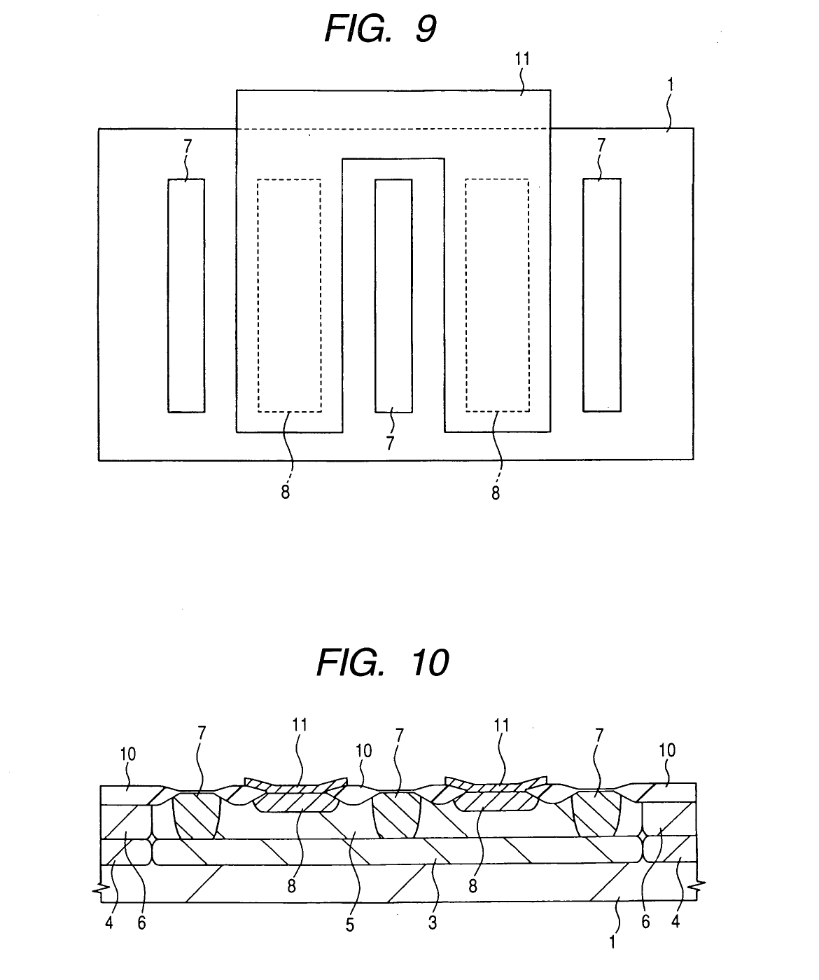

Next, as shown in FIG. 8, an n-type impurity (phosphorus) is ion implanted into part of the collector region 5 to form an n-type collector extraction region 7. Subsequently, as shown in FIGS. 9 and 10, a p-type polysilicon film deposited over the substrate 1 by a CVD method is subjected to patterning to form an outer base layer 11 whose planar shape is in a U form. Thereafter, the substrate 1 is thermally treated to permit the p-type impurity in the outer base layer 11 to be diffused into part of the surface of the collector region 5, thereby self-alignedly forming a p-type intrinsic base region 8.

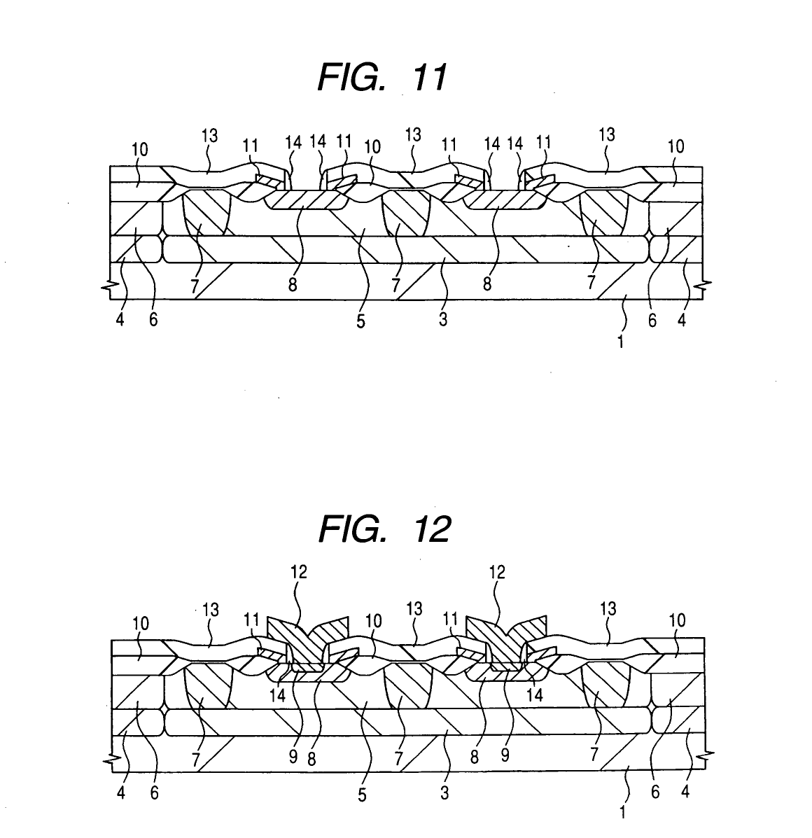

Next, as shown in FIG. 11, a silicon oxide film 13 is deposited over the substrate 1 by a CVD method, followed by etching the silicon oxide film 13 at a portion formed over the intrinsic base region 8 and also the outer base layer 11 below the portion, thereby forming an opening where part of the intrinsic base region 8 is exposed. Subsequently, the silicon oxide film 13 deposited over the substrate 1 by the CVD method is etched back to form a side wall insulating film 14 at side walls of the opening. The side wall insulating film 14 is formed to electrically separate an emitter extraction layer 12 formed in a subsequent step and the outer base layer 11 from each other.

Next, as shown in FIG. 12, an n-type polysilicon film deposited over the substrate 1 by a CVD method is subjected to patterning to form an emitter extraction layer 12 over the intrinsic base region 8. The substrate is subsequently thermally treated to diffuse an n-type impurity in the emitter extraction layer 12 into part of the surface of the intrinsic base region 8, thereby self-alignedly forming an n-type emitter region 9.

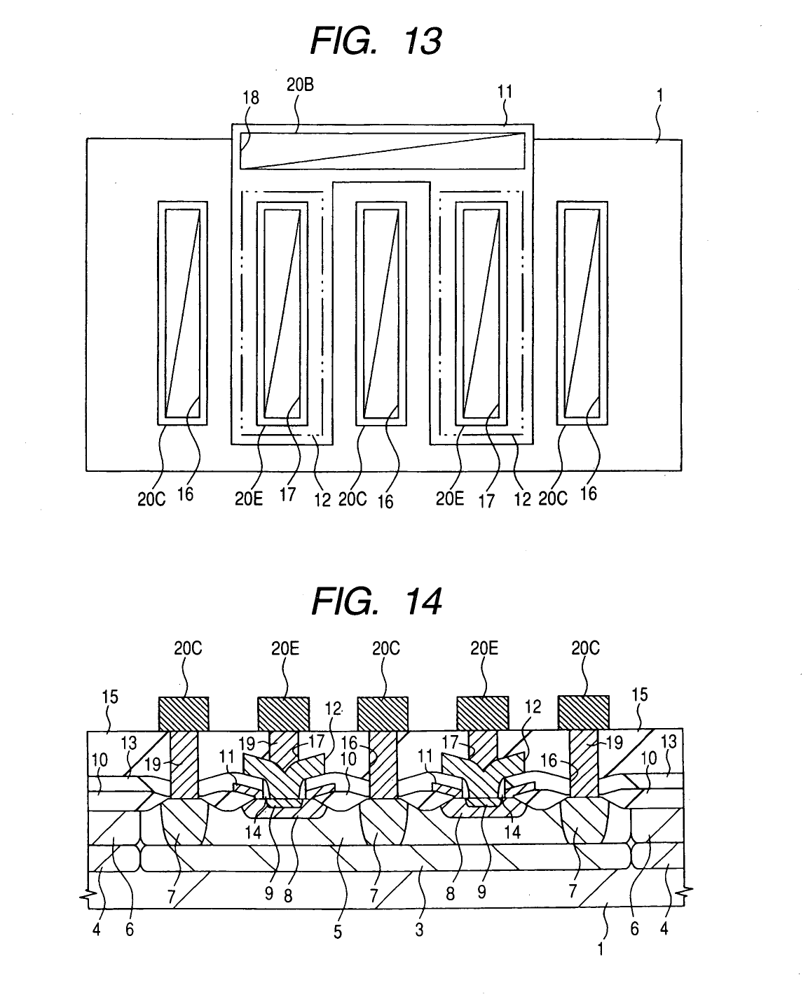

As shown in FIGS. 13, 14 and 15, an interlayer insulating film 15 made of a silicon oxide film is deposited over the emitter extraction layer 12 by a CVD method, and contact holes 16, 17, 18 are, respectively, formed in the interlayer insulating film 15, followed by forming metal plugs 19 made, for example, of a tungsten film inside the contact holes 16, 17, 18. Next, an aluminum alloy film deposited over the interlayer insulating film 15 by a sputtering method is patterned in a desired form to form a collector electrode 20C above the collector extraction region 7, an emitter electrode 20E above the emitter extraction layer 12 and a base electrode 20B above the outer base layer 11, respectively.

As stated hereinbefore, the collector electrode 20C and the emitter electrode 20E are so arranged that the long sides thereof are set parallel to each other and central portions are arranged to stand in the same line within a plane parallel to the main surface of the substrate 1. On the other hand, the base electrode 20B is so set that individual long sides thereof are intersected at right angles with individual long sides of the collector electrode 20C and emitter electrode 20E, and is located at the outside of a line connecting the collector electrode 20C and emitter electrode 20E at one end thereof.

Thereafter, interlayer insulating films 21, 27 are deposited and second metal wiring layers 22C, 22E, 22B and third metal wiring layers 28C, 28E, 28B are formed, respectively, to complete a bipolar transistor shown in FIGS. 1 to 4.

### EMBODIMENT 2

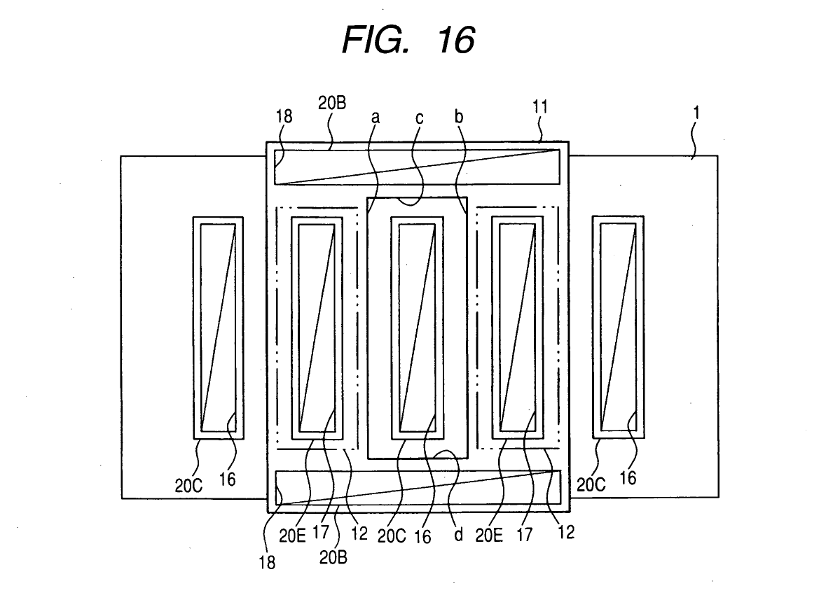

FIG. 16 is a plan view of an essential part of a bipolar transistor according to this embodiment. The difference from the bipolar transistor of Embodiment 1 resides in that the planar shape of the outer base layer is changed, the base electrode 20B is provided at the outside of a line connecting the collector electrode 20C and the emitter electrode 20E at one end thereof and also at the outside of a line connecting the other ends, respectively, and the respective base electrodes 20B are electrically connected to the outer base layer 11 via the contact holes 18 provided therebelow. The outer base layer 11 is set at a first portion (a) and a second portion (b) that are positioned at opposite sides of the collector electrode 20C, and at portions that are formed along directions intersecting (substantially at right angles) with the first portion (a) and the second portion (b) and thus, consist of a third portion (c) and a fourth portion (d) connecting the first portion (a) with the second portion (b), respectively. More particularly, the planar shape of the outer base layer 1 that is parallel to the main surface of the substrate 1 is one which surrounds the collector electrode 20C with the first to fourth portions (a to d).

The outer base layer 11 of the embodiment having such a planar shape as mentioned above is larger in area than the outer base layer 11 of Embodiment 1 having a planar shape of U form, resulting in a correspondingly increased base-collector MOS capacitance (C_{BX}). One the other hand, since two base electrodes 20B are formed, the contact resistance between the outer base layer 11 and the base electrode 20B decreases, with a decreasing base resistance (rb) over the case of Embodiment 1. According to the afore-indicated equation (1), this eventually leads to an improved power gain (PG).

Thus, according to this embodiment, the power gain (PG) can be improved over the bipolar transistor shown in FIGS. 17 and 18. Moreover, the distance between the collector electrode 20C and the emitter electrode 20E becomes smaller than with the case of the bipolar transistor shown in FIGS. 17 and 18, thus ensuring a smaller collector resistance (Rc) and improved cutoff frequency (f_{T}) and 1 dB gain compression output power.

### EMBODIMENT 3

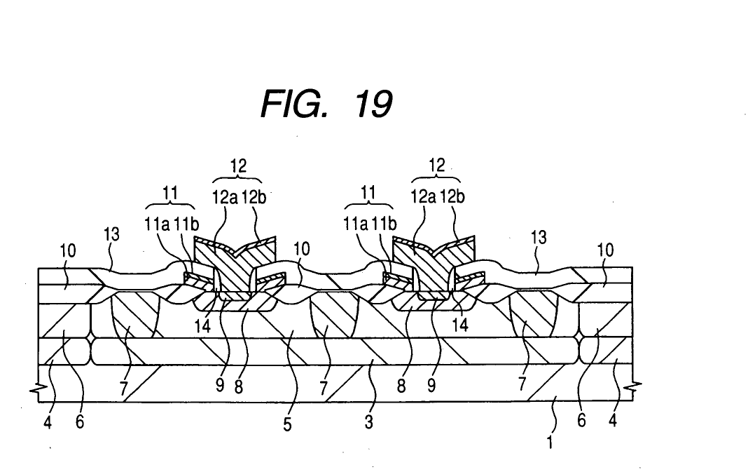

Although the outer base layer 11 of Embodiments 1 and 2 has been formed of a polysilicon film, the outer base layer 11 may be constituted, for example, of a polycide film, e.g. a built up film of a polysilicon film 11a on which a film 11b of a metal such as cobalt is formed, for example, as shown in FIG. 19. This arrangement permits a contact resistance of the outer base film 11 and a base electrode (20B) connected therewith to be reduced. Accordingly, if the area of the outer base layer 11 is reduced, then the base resistance (rb) could be further lessened.

Likewise, if the emitter extraction layer 12 is constituted of a polycide film wherein a metal film 12b such as cobalt is built up on a polysilicon film 12a, the contact resistance between the emitter extraction layer 12 and the emitter electrode (20E) connected therewith could be reduced.

Although the invention has been particularly described based on the embodiments, the invention should not be construed as limiting to these embodiments. Many alterations and changes may be made without departing from the spirit of the invention.

What is claimed is:

1. A semiconductor device including a bipolar transistor, said bipolar transistor comprising:
a collector region, an intrinsic region and an emitter region each formed over a semiconductor substrate;
a collector electrode electrically connected to said collector region,
a base electrode electrically connected to said intrinsic base region via an outer base layer; and
an emitter electrode electrically connected to said emitter region via an emitter extraction layer,
wherein said collector electrodes and said emitter electrode are, respectively, provided plurally and arranged alternately side by side, and
wherein said outer base layer is made of first and second portions located at opposite sides of said collector electrode, and a third portion that is set in a direction intersecting with said first and second portions and connecting said first and second portions therewith.

2. The semiconductor device according to claim 1, wherein only one of said plurality of collector electrodes is disposed at an inside of said outer base layer within a plane parallel to a main surface of said semiconductor substrate.

3. The semiconductor device according to claim 1, wherein said outer base layer is formed of a silicon layer or silicide layer formed over said intrinsic base region, and said base electrode is formed of a metal layer formed over said outer base layer.

4. The semiconductor device according to claim 1, wherein said intrinsic region is formed of a Si—Ge semiconductor.

5. The semiconductor device according to claim 1, wherein said intrinsic base region is formed of a Si—Ge semiconductor, and said outer base layer is formed of a silicon layer or silicide layer directly connected to said intrinsic base region.

6. The semiconductor device according to claim 5, wherein said intrinsic base region has part of an impurity contained in said outer base layer diffused therein.

7. The semiconductor device according to claim 1, wherein a central portion of each of the plurality of collector electrodes and a central portion of each of the plurality of emitter electrodes stand substantially in the same line within a plane parallel to a main surface of said semiconductor substrate.

8. The semiconductor device according to claim 1, wherein said bipolar transistor constitutes a device for communication apparatus.

9. The semiconductor device according to claim 8, wherein said bipolar transistor is used as a high frequency unit of the device for communication apparatus.

10. The semiconductor device according to claim 9, wherein said high frequency unit is a power amplifier or low noise amplifier.

11. The semiconductor device according to claim 8, wherein an operating frequency of said device for communication apparatus is 1 GHz or over.

12. A semiconductor device including a bipolar transistor, said bipolar transistor comprising:
a collector region, an intrinsic region and an emitter region each formed over a semiconductor substrate;
a collector electrode electrically connected to said collector region,
a base electrode electrically connected to said intrinsic base region via an outer base layer; and
an emitter electrode electrically connected to said emitter region via an emitter extraction layer,
wherein said collector electrode and said emitter electrode are, respectively, provided plurally and arranged alternately side by side,
wherein a central portion of each of the plurality of collector electrodes and a central portion of the plurality of emitter electrodes stand in the same line within a plane parallel to a main surface of said semiconductor substrate, and
wherein a central portion of said base electrode is outside said same line.

13. The semiconductor device according to claim 12, wherein the respective planar shapes of said collector electrode, said base electrode and said emitter electrode are rectangular, and
wherein a long side of said base electrode intersects at right angles with the respective long sides of said collector electrode and said base electrode within a plane parallel to a main surface of said semiconductor substrate.

14. The semiconductor device according to claim 12, wherein a planar shape of said outer base layer is in a U form.

15. The semiconductor device according to claim 12, wherein a planar shape of said outer base layer parallel to a main surface of said semiconductor substrate includes first and second portions set at opposite sides of said collector electrode and third and fourth portions set in directions intersecting with said first and second portions and connecting said first and second portions therewith, and is in a form surrounding said collector electrode by means of the first, second, third and fourth portions.

16. The semiconductor device according to claim 1, wherein said outer base layer has a planar shape parallel to the main surface of said semiconductor substrate, the planar shape being in a U form constituted of the first, second and third portions.

17. A method for manufacturing a semiconductor device, comprising the steps of:
(a) forming an epitaxial layer of a first conduction type over a main surface of a semiconductor substrate wherein a buried layer of the first conduction type constituting part of a collector region has been formed;
(b) forming a collector extraction region of the first conduction type at part of said epitaxial layer so that a bottom of said collector extraction region contacts said buried layer;
(c) forming an intrinsic base region of a second conduction type at other part of said epitaxial layer and forming an outer base layer made of a first conductor film containing a silicon film of the second conduction type over said intrinsic base region;
(d) forming an emitter region of the first conduction type at part of a surface of said intrinsic base region and forming, over said emitter region, an emitter extraction layer that is electrically isolated from said outer base layer via an insulating film and is made of a second conductor film containing a silicon film of the first conduction type; and
(e) forming an interlayer insulating film over said emitter extraction layer, followed by forming a collector electrode over said interlayer insulating film formed above said collector extraction region, electrically connecting said collector electrode and said collector extraction region through a first contact hole formed in said interlayer insulating film, forming an emitter electrode over said interlayer insulating film formed above said emitter extraction layer, electrically connecting said emitter electrode and said emitter extraction layer via a second contact hole formed in said interlayer insulating film, forming a base electrode over said interlayer insulating film formed above said outer base layer, and electrically connecting said base electrode with said outer base layer via a third contact hole formed in said interlayer insulating film,
wherein said collector electrode and said emitter electrode are, respectively, provided plurally in number and a plurality of collector electrodes and a plurality of emitter electrodes are alternately arranged side by side within a plane parallel to the main surface of said semiconductor substrate, and a planar shape of said outer base layer is in a U form.

18. The method according to claim 17, wherein said base electrode is located outside a line connecting said collector electrode with said emitter at one end thereof, and a long side of said base electrode is arranged to intersect at right angles with the respective long sides of said collector electrode and said emitter electrode.

19. A method for manufacturing a semiconductor device, comprising the steps of:
(a) forming an epitaxial layer of a first conduction type over a main surface of a semiconductor substrate wherein a buried layer of the first conduction type constituting part of a collector region has been formed;
(b) forming a collector extraction region of the first conduction type at part of said epitaxial layer so that a bottom of said collector extraction region contacts said buried layer;
(c) forming an intrinsic base region of a second conduction type at other part of said epitaxial layer and forming an outer base layer made of a first conductor film containing a silicon film of the second conduction type over said intrinsic base region;
(d) forming an emitter region of the first conduction type at part of a surface of said intrinsic base region and forming, over said emitter region, an emitter extraction layer that is electrically isolated from said outer base layer via an insulating film and is made of a second conductor film containing a silicon film of the first conduction type; and
(e) forming an interlayer insulating film over said emitter extraction layer, followed by forming a collector electrode over said interlayer insulating film formed above said collector extraction region, electrically connecting said collector electrode and said collector extraction region through a first contact hole formed in said interlayer insulating film, forming an emitter electrode over said interlayer insulating film formed above said emitter extraction layer, electrically connecting said emitter electrode and said emitter extraction layer via a second contact hole formed in said interlayer insulating film, forming a base electrode over said interlayer insulating film formed above said outer base layer, and electrically connecting said base electrode with said outer base layer via a third contact hole formed in said interlayer insulating film,
wherein said collector electrode and said emitter electrode are, respectively, provided plurally in number and a plurality of collector electrodes and a plurality of emitter electrodes are alternately arranged side by side within a plane parallel to the main surface of said semiconductor substrate, a planar shape of said outer base layer is in a rectangular form, and said base electrode is, respectively, set outside a line connecting said collector electrode with said emitter electrode at one end thereof and also outside a line connecting said collector electrode with said emitter electrode at the other end thereof.
